(19) United States
(12) Patent Application Publication
(10) Pub. No.: US 2026/0214843 A1
(43) Pub. Date: Jul. 23, 2026

(54) LIQUID COOLING CABINET BEARING APPARATUS

(71) Applicant: BEIJING YOUZHUJU NETWORK TECHNOLOGY CO., LTD., Beijing (CN)

(72) Inventors: Chen WANG, Beijing (CN); Tangbo JING, Beijing (CN); Xioliang GUO, Beijing (CN); Qi ZHANG, Beijing (CN); Jian WANG, Beijing (CN); Bing Gao, Beijing (CN)

(21) Appl. No.: 19/140,303

(22) PCT Filed: Jan. 9, 2024
(86) PCT No.: PCT/CN2024/071413

§ 371 Date: Jun. 17, 2025

(30) Foreign Application Priority Data
Jan. 16, 2023 (CN) 202310077540.9

(51) Int. Cl. H05K 7/20

(52) U.S. Cl. CPC H05K 7/20272; H05K 7/20236; H05K 7/20772

(57) ABSTRACT

The embodiment of the disclosure provides a liquid cooling cabinet bearing apparatus comprising: a rack comprising a plurality of vertical support structures and at least one layer of mounting bases supported by the vertical support structures, each layer of mounting bases comprise a plurality of mounting bases for bearing corresponding liquid cooling cabinet respectively, and at least part of the vertical support structures is provided with a pipeline arrangement channel; a cooling water supply pipe comprising a water supply horizontal pipe, at least one water supply longitudinal pipe and a water supply branch pipe; a cooling water return pipe, comprising a water return horizontal pipe, at least one water return longitudinal pipe and a water return branch pipe, and an electrical line disposed outside the pipeline arrangement channel and adapted to be electrically connected to the corresponding liquid cooling cabinet.

This application claims priority to Chinese Patent Application No. 202310077540.9, entitled “LIQUID COOLING CABINET BEARING APPARATUS” filed on Jan. 16, 2023, the entirety of which is incorporated herein by reference.

### FIELD

Embodiments of the present disclosure generally relate to the technical field of electronic device cooling, and more particularly, to a liquid cooling cabinet bearing apparatus.

### BACKGROUND

While the energy consumption of data centers is increasing day by day, with the continuous increasing in power density of chips, the power density of a single cabinet of general-purpose servers will continue to increase significantly in a foreseeable future time period. When the power density exceeds a certain limitation, a traditional air cooling mode may not solve heat dissipation problems. Furthermore, natural cooling in the air cooling mode is greatly affected by local meteorological conditions of the data centers, thus it is difficult to achieve natural cooling throughout a year in most regions.

However, in current situation of energy shortage and rapid increase in energy costs, the data center needs to reduce the energy consumption of cooling heat dissipation and the power usage efficiency (PUE) while ensuring high performance, so as to save energy and reduce consumption, energy usage and carbon emission.

Immersion cooling, that is, a cooled object directly contacts a refrigerant (also referred to as a coolant), involves completely immersing components such as a server motherboard, a central processing unit (CPU) and a memory in the refrigerant. In this way, the transfer of heat may be achieved by using a temperature difference or a phase change of the liquid, thereby enabling heat dissipation with high heat flux density. However, a liquid cooling cabinet of an immersion liquid cooling system is generally a horizontal structure so as to facilitate vertically plugging-in/out for maintaining the server, thus the occupied area is larger than that of an air cooling cabinet, and a height space may not be fully utilized like a cabinet of an air cooling server.

### SUMMARY

A purpose of the present disclosure is to provide a liquid cooling cabinet bearing apparatus to at least partially solve the problems described above.

In an aspect of the present disclosure, there is provided a liquid cooling cabinet bearing apparatus, comprising: a rack comprising a plurality of vertical support structures and at least one layer of mounting bases supported by the plurality of vertical support structures, wherein each layer of the mounting bases comprises a plurality of mounting bases for bearing a corresponding liquid cooling cabinet respectively, and at least a part of the plurality of vertical support structures is provided with a pipeline arrangement channel extending along a length direction thereof; a cooling water supply pipe comprising a water supply horizontal pipe, at least one water supply longitudinal pipe in communication with the water supply horizontal pipe, and a water supply branch pipe in communication with the at least one water supply longitudinal pipe and configured to provide cooling water to a corresponding liquid cooling cabinet, wherein the water supply horizontal pipe is disposed outside the pipeline arrangement channel, and the at least one water supply longitudinal pipe and a corresponding water supply branch pipe are disposed in a corresponding pipeline arrangement channel; a cooling water return pipe comprising a water return horizontal pipe, at least one water return longitudinal pipe in communication with the water return horizontal pipe, and a water return branch pipe in communication with the at least one water return longitudinal pipe and configured to receive heated cooling water from a corresponding liquid cooling cabinet, wherein the water return horizontal pipe is disposed outside the pipeline arrangement channel, and the at least one water return longitudinal pipe and a corresponding water return branch pipe are disposed in a corresponding pipeline arrangement channel; and an electrical line disposed outside the pipeline arrangement channel and adapted to be electrically connected to a corresponding liquid cooling cabinet.

In some embodiments, the water supply horizontal pipe and the water return horizontal pipe are disposed below the rack, and the electrical line is connected to a corresponding liquid cooling cabinet from a top of the rack.

In some embodiments, the water supply horizontal pipe and the water return horizontal pipe are disposed below a floor or on the ground.

In some embodiments, the electrical line comprises a power supply line and a network line; the power supply line comprises a horizontal power supply wire, at least one longitudinal power supply wire connected to the horizontal power supply wire, and a power supply branch wire connected to the at least one longitudinal power supply wire, wherein the power supply branch wire is adapted to be electrically connected to a corresponding liquid cooling cabinet; the network line comprises a horizontal network wire, at least one longitudinal network wire connected to the horizontal network wire, and a network branch wire connected to the at least one longitudinal network wire, wherein the network branch wire is adapted to be electrically connected to a corresponding liquid cooling cabinet; and the horizontal power supply wire and the horizontal network wire are disposed in a horizontal cable tray above a ceiling, and the at least one longitudinal power supply wire and the at least one longitudinal network wire are disposed in a vertical cable tray.

In some embodiments, the electrical line comprises a power supply line and a network line; the power supply line comprises a horizontal power supply wire, at least one longitudinal power supply wire connected to the horizontal power supply wire, and a power supply branch wire connected to the at least one longitudinal power supply wire, wherein the power supply branch wire is adapted to be electrically connected to a corresponding liquid cooling cabinet; the network line comprises a horizontal network wire, at least one longitudinal network wire connected to the horizontal network wire, and a network branch wire connected to the at least one longitudinal network wire, wherein the network branch wire is adapted to be electrically connected to a corresponding liquid cooling cabinet; wherein the water supply horizontal pipe, the water return horizontal pipe, the horizontal power supply wire and the horizontal network wire are arranged in any one of the following ways: the water supply horizontal pipe, the water return horizontal pipe, the horizontal power supply wire and the horizontal network wire are all disposed below a floor; the water supply horizontal pipe, the water return horizontal pipe, the horizontal power supply wire and the horizontal network wire are all disposed above a ceiling; the water supply horizontal pipe, the water return horizontal pipe and the horizontal power supply wire are disposed below the floor, and the horizontal network wire is disposed above the ceiling; the water supply horizontal pipe, the water return horizontal pipe and the horizontal power supply wire are disposed above the ceiling, and the horizontal network wire is disposed below the floor; the water supply horizontal pipe, the water return horizontal pipe and the horizontal network wire are disposed below the floor, and the horizontal power supply wire is disposed above the ceiling; or the water supply horizontal pipe, the water return horizontal pipe and the horizontal network wire are disposed above the ceiling, and the horizontal power supply wire is disposed below the floor.

In some embodiments, the rack comprises two layers of the mounting bases.

In some embodiments, the liquid cooling cabinet bearing apparatus further comprises a plurality of groups of blind mate interfaces, wherein each group of blind mate interfaces is adapted to be connected to a water supply connector, a water return connector, a power supply connector and a network connector of a corresponding liquid cooling cabinet.

In some embodiments, the at least one layer of mounting bases is provided with a mounting hole for fixing a corresponding liquid cooling cabinet through a fastener.

In some embodiments, the rack is made of steel structure, and is provided with stairs and operation and maintenance channels.

In some embodiments, the liquid cooling cabinet bearing apparatus further comprises an operation and maintenance assembly separated from the rack and comprising: a base; a roller, disposed at a bottom of the base; a vertical rod, disposed at the top of the base; and a supporting part for supporting the liquid cooling cabinet, the supporting part being disposed on the vertical rod and able to move along the vertical rod to a same height as each layer of the mounting bases.

In some embodiments, the operation and maintenance assembly further comprises a temporary cooling apparatus for temporarily providing a cold quantity to the liquid cooling cabinet on the supporting part.

According to the embodiments of the present disclosure, liquid cooling cabinets of the immersion liquid cooling system are mounted in a stack through using the liquid cooling cabinet bearing apparatus, such that the height space of a machine room of the data center is utilized to the maximum extent and a stereoscopic immersion liquid cooling data center is constructed, thereby the power density of the unit area of the machine room may be further improved, and the occupied area may be saved.

It should be understood that the content described in the summary is not intended to limit the key features or important features of the embodiments of the present disclosure, nor is it intended to limit the scope of the present disclosure. Other features of the present disclosure will become readily understood through the following description.

### BRIEF DESCRIPTION OF DRAWINGS

The above and other features, advantages, and aspects of various embodiments of the present disclosure will become more apparent from the following detailed description taken in conjunction with the accompanying drawings. In the drawings, the same or similar reference numbers refer to the same or similar elements, wherein:

FIG. 1 illustrates a schematic diagram of an immersion liquid cooling system according to an embodiment of the present disclosure;

FIG. 2 illustrates a schematic structural diagram of a liquid cooling cabinet according to an embodiment of the present disclosure; and

FIG. 3 illustrates a schematic structural diagram of a liquid cooling cabinet bearing apparatus according to an embodiment of the present disclosure.

### DETAILED DESCRIPTION

Preferred embodiments of the present disclosure will be described in more detail below with reference to the accompanying drawings. While the preferred embodiments of the present disclosure are shown in the drawings, it should be understood that the present disclosure may be implemented in various forms and should not be limited by the embodiments set forth herein. Rather, these embodiments are provided to make this disclosure more thorough and complete, and to fully convey the scope of the present disclosure to those skilled in the art.

As used herein, the term “comprising” and variations thereof represent openness, i.e., “including but not limited to”. Unless specifically stated, the term “or” means “and/or”. The term “based on” means “based at least in part on”. The terms “an example embodiment” and “an embodiment” mean “at least one example embodiment”. The term “another embodiment” means “at least one other embodiment”. The terms “first,” “second,” and the like may refer to different or identical objects.

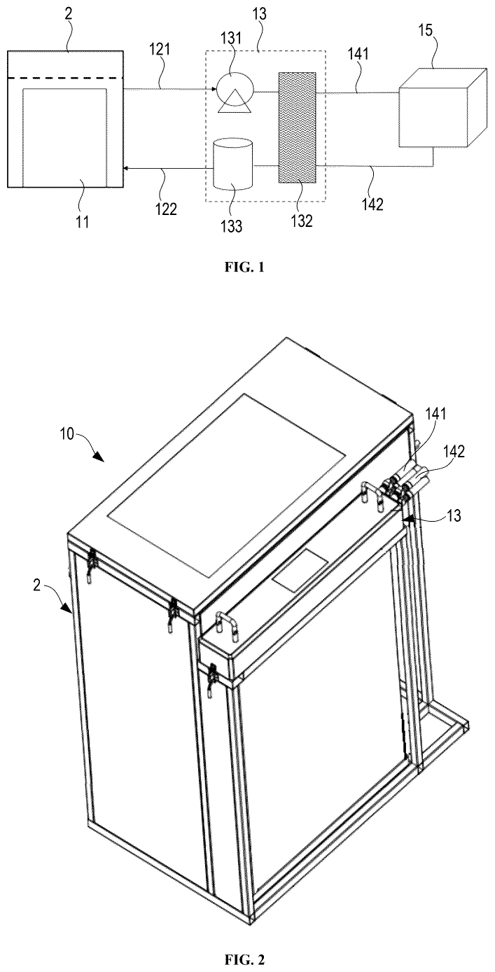

FIG. 1 illustrates a schematic diagram of an immersion liquid cooling system according to an embodiment of the present disclosure. As shown in FIG. 1, the immersion liquid cooling system generally includes a sealed cavity 2, a heat exchange unit 13 and a cooling tower 15. An electronic device 11, such as a server motherboard or a switch, may be directly immersed in the coolant in the sealed cavity 2. The heat generated by CPUs and various electronic components during operation of the electronic device 11 may increase the temperature of the coolant. The heated coolant is provided to the heat exchange unit 13 via a coolant return pipe 121, and the coolant is cooled by the heat exchange unit 13 by using the cold quantity provided by the cooling tower 15 and returns to the sealed cavity 2 again via a coolant supply pipe 122.

In one embodiment, the heat exchange unit 13 may include a pump 131, a plate heat exchanger 132, and a filter 133. The pump 131 is connected to the sealed cavity 2 via the coolant return pipe 121 to pump the heated coolant in the sealed cavity 2 to the plate heat exchanger 132. The plate heat exchanger 132 is connected to the cooling tower 15 via a cooling water supply pipe 141 and a cooling water return pipe 142. The plate heat exchanger 132 receives the cooling water from the cooling tower 15 via the cooling water supply pipe 141, and cools the heated coolant received from the sealed cavity 2 by using the received cooling water. The plate heat exchanger 132 returns the cooled coolant to the sealed cavity 2 through the filter 133 and the coolant supply pipe 122. The plate heat exchanger 132 returns the heated cooling water to the cooling tower 15.

In some embodiments, the heat exchange unit 13 may further include accessories such as a pipeline sensor and a valve, to implement the corresponding monitoring and flow control function.

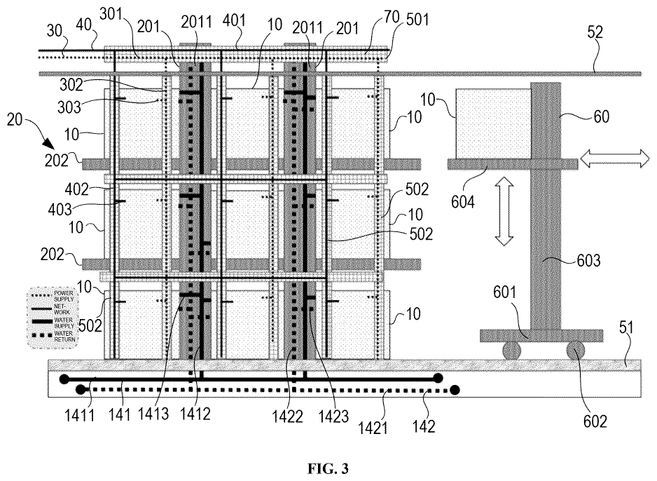

In some embodiments, as shown in FIG. 2, the sealed cavity 2 and the heat exchange unit 13 may be integrated together to form a liquid cooling cabinet 10. The heat exchange unit 13 is formed on a side wall of the sealed cavity 2, and the heat exchange unit 13 can be connected to the cooling tower 15 via the cooling water supply pipe 141 and the cooling water return pipe 142. In other embodiments, the liquid cooling cabinet 10 may have other arrangements, the embodiments of the present disclosure are not limited in this regard.

In an embodiment according to the present disclosure, the liquid cooling cabinet 10 is configured to perform immersion cooling on the electronic device 11. The liquid cooling cabinet 10 receives the cooling water via the cooling water supply pipe 141 and uses the cooling water to cool the coolant in the liquid cooling cabinet 10, and the heated cooling water returns to the cooling tower 15 via the cooling water return pipe 142. In this way, efficient cooling of the electronic device 11 is achieved.

As for the liquid cooling cabinet 10, since the heat dissipation effect is better when the coolant is in direct contact with the cooled object, and the heat dissipation problem of all components of the electronic device 11 may be solved at once, therefore no additional fans, heat sinks and the like are required. Immersion liquid cooling is a cooling mode with the highest cooling efficiency and optimal effect in conventional cooling modes, which has the following advantages:
1. The coolant is in direct contact with the heating device without contact thermal resistance;
2. The specific heat of the liquid is higher than that of air, the heat transferred per unit volume (i.e., the heat dissipation efficiency) is up to thousands of times higher than that of air cooling, wherein the heat exchange efficiency is high and thus the heat dissipation problem of the server with super high heat flux density may be solved;
3. The immersion liquid cooling may solve the heat dissipation problem of all components of the server at once, while only heat of CPUs are dissipated by the liquid in cold plate type liquid cooling, and the rest of the heat generating components still need to be dissipated by air cooling, which leads to a hybrid cooling of air and liquid cooling;
4. The environment of the immersion liquid cooling is suitable for electronic components such as CPUs to not be affected by external temperature, humidity, air quality and the like, and the temperature is constant, thereby the reliability and the service lifespan of the electronic components may be improved;
5. The immersion liquid cooling may directly use the cold water of the outdoor cooling tower for heat dissipation, which is energy saving and high efficiency, so that natural cooling through a year may be achieved in any meteorological area and the PUE can reach about 1.1;
6. The immersion liquid cooling employs insulated coolant, thus there is not a risk of short-circuit of the server even when it is leaked;
7. The immersion liquid cooling may greatly reduce the noise of the machine room due to the elimination of the fan of the server, thereby achieving the effect of a muted machine room;
8. The immersion liquid cooling does not require an air cooling facility such as a refrigerating machine and a constant temperature and humidity air conditioner for the machine room, and also not require air supply under the floor and isolation of cold and hot channels, which simplifies the structure of the machine room and reduces the difficulty and engineering quantity of the construction of the machine room.

Since an upper cover of the liquid cooling cabinet 10 needs to be opened to vertically plug in/out the server motherboard for maintenance, the liquid cooling cabinet 10 is generally a horizontal structure, which is similar to the placement of the cabinet of the air cooling server on the ground of the data center machine room horizontally. Therefore, the occupied area of the liquid cooling cabinet 10 of the immersion liquid cooling system is greater than that of the air cooling cabinet, and the height space cannot be fully utilized like the cabinet of the air cooling server. When the power density of the server is high, the power density per square meter of the immersion liquid cooling machine room may exceed that of an air cooling machine room. However, when the power density of the immersion liquid cooling system has not reached a predetermined level, the power density per square meter of the immersion liquid cooling machine room may be even lower than that of an air cooling machine room. This is contrary to the original intention of the high heat dissipation efficiency of immersion liquid cooling and the improvement of the power density of the machine room.

A purpose of the embodiments of the present disclosure is to make full use of the height space within the data center machine room, arrange the liquid cooling cabinet 10 of the immersion liquid cooling system in a stack stereoscopically to improve the power density per square meter in the machine room, and save the occupied area of the machine room. The principle of the present disclosure will be described below with reference to FIG. 3.

FIG. 3 is a schematic structural diagram of a liquid cooling cabinet bearing apparatus according to an embodiment of the present disclosure. As shown in FIG. 3, the liquid cooling cabinet bearing apparatus described herein generally includes a rack 20, a cooling water supply pipe 141, a cooling water return pipe 142 and an electrical line 70. The cooling water supply pipe 141 is configured to supply cooling water to the liquid cooling cabinet 10, and the cooling water return pipe 142 is configured to receive the heated cooling water from the liquid cooling cabinet 10. The electrical line 70 is configured to provide power to the liquid cooling cabinet 10, or additionally provide a control signal to the liquid cooling cabinet 10 or receive a signal indicating the operation state thereof from the liquid cooling cabinet 10. In FIG. 3, the cooling water supply pipe 141 is represented by a thick solid line, and the cooling water return pipe 142 is represented by a thick dotted line. The electrical line 70 may include at least one of a power supply line 30 and a network line 40. The power supply line 30 is represented by a thin dotted line and configured to provide power to the liquid cooling cabinet 10. The network line 40 is represented by a thin solid line and configured to provide a control signal to the liquid cooling cabinet 10 or receive a signal indicating its operation state from the liquid cooling cabinet 10.

In one embodiment, the rack 20 is made of steel structure. The rack 20 includes a plurality of vertical support structures 201 and at least one layer of mounting bases 202 supported by the plurality of vertical support structures 201. Each layer of the mounting bases 202 includes a plurality of mounting bases 202 for bearing a corresponding liquid cooling cabinet 10 respectively. At least a part of the plurality of vertical support structures 201 is provided with a pipeline arrangement channel 2011 extending along a length direction thereof. The pipeline arrangement channel 2011 is configured to arrange the cooling water supply pipe 141 and the cooling water return pipe 142.

Two vertical support structures 201 are shown in FIG. 3 as an example to describe the principles of the present disclosure. However, it should be understood that the rack 20 may include more vertical support structures 201, which is not limited in the embodiments of the present disclosure. In addition, in the embodiments of the present disclosure, the pipeline arrangement channel 2011 may be arranged in only a part of the vertical support structures 201, or in all the vertical support structures 201.

In addition, two layers of mounting bases 202 are shown in FIG. 3 as an example to describe the principles of the present disclosure. However, it should be understood that the rack 20 may include only one layer of mounting bases 202, or may include more than two layers of mounting bases 202, which is not limited in the embodiments of the present disclosure.

As shown in FIG. 3, a layer of liquid cooling cabinets 10 may be disposed on each layer of mounting bases 202. Each of the liquid cooling cabinets 10 may be fixedly mounted on the corresponding mounting base 202 through a suitable fastener, such as a bolt. In addition, a layer of liquid cooling cabinets 10 may be disposed on the floor 51 or the ground.

As shown in FIG. 3, the cooling water supply pipe 141 includes a water supply horizontal pipe 1411, at least one water supply longitudinal pipe 1412 in communication with the water supply horizontal pipe 1411, and a water supply branch pipe 1413 in communication with the at least one water supply longitudinal pipe 1412 configured to provide cooling water to the corresponding liquid cooling cabinet 10. The water supply horizontal pipe 1411 is disposed outside the pipeline arrangement channel 2011 and located below the rack 20. The water supply longitudinal pipe 1412 and the corresponding water supply branch pipe 1413 are disposed in the corresponding pipeline arrangement channel 2011. The water supply longitudinal pipe 1412 extends along the length direction of the corresponding pipeline arrangement channel 2011. Each water supply branch pipe 1413 extends substantially horizontally relative to the water supply longitudinal pipe 1412 and is connected to the corresponding liquid cooling cabinet 10 respectively. The water supply horizontal pipe 1411 may be connected to the cooling tower 15 to receive cooling water from the cooling tower 15 and provide the cooling water to the water supply longitudinal pipe 1412 after the pressurization via the pump. The water supply longitudinal pipe 1412 may provide the cooling water to the liquid cooling cabinets 10 at different heights via the water supply branch pipe 1413.

In some embodiments, the water supply longitudinal pipe 1412 may have a flow balancing structure, thereby ensuring that the liquid cooling cabinets 10 at different heights may obtain balanced cooling water flow.

As shown in FIG. 3, the cooling water return pipe 142 includes a water return horizontal pipe 1421, at least one water return longitudinal pipe 1422 in communication with the water return horizontal pipe 1421, and a water return branch pipe 1423 in communication with the at least one water return longitudinal pipe 1422 and configured to receive the heated cooling water from the corresponding liquid cooling cabinet 10. The water return horizontal pipe 1421 may be connected to the cooling tower 15. The water return horizontal pipe 1421 is disposed outside the pipeline arrangement channel 2011 and located below the rack 20. The water return longitudinal pipe 1422 and the corresponding water return branch pipe 1423 are disposed in the corresponding pipeline arrangement channel 2011. The water return longitudinal pipe 1422 extends along the length direction of the corresponding pipeline arrangement channel 2011. Each water return branch pipe 1423 extends substantially horizontally relative to the water return longitudinal pipe 1422 and is connected to a corresponding liquid cooling cabinet 10 respectively. The heated cooling water in the liquid cooling cabinet 10 may be returned to the cooling tower 15 via the water return branch pipe 1423, the water return longitudinal pipe 1422, and the water return horizontal pipe 1421.

The electrical line 70 is disposed outside the pipeline arrangement channel 2011 and adapted to be electrically connected to a corresponding liquid cooling cabinet 10. The electrical line 70 may include a power supply line 30 and a network line 40. The power supply line 30 is configured to provide power to the liquid cooling cabinet 10. The network line 40 is configured to provide a control signal to the liquid cooling cabinet 10 or receive a signal from the liquid cooling cabinet 10 indicating an operation state thereof.

In the embodiments of the present disclosure, the liquid cooling cabinet 10 of the immersion liquid cooling system is mounted in a stack through using the liquid cooling cabinet bearing apparatus, such that the height space of a machine room of the data center may be utilized to the maximum extent and a stereoscopic immersion liquid cooling data center may be constructed, thereby the power density of the unit area of the machine room may be further improved, and the occupied area may be saved. In addition, by disposing the water supply longitudinal pipe 1412 and the corresponding water supply branch pipe 1413 and the water return longitudinal pipe 1422 and the corresponding water return branch pipe 1423 in the pipeline arrangement channel 2011, the isolation between water and electricity can be at least partially realized, and the safety of the immersion liquid cooling system is improved.

In some embodiments, as shown in FIG. 3, the water supply horizontal pipe 1411 and the water return horizontal pipe 1421 are disposed below the rack 20, and the electrical line 70 is connected to the corresponding liquid cooling cabinet 10 from the top of the rack 20. The electrical line 70 includes a power supply line 30 and a network line 40. The power supply line 30 includes a horizontal power supply wire 301, at least one longitudinal power supply wire 302 connected to the horizontal power supply wire, and a power supply branch wire 303 connected to the at least one longitudinal power supply wire 302. The power supply branch wire 303 is adapted to be electrically connected to a corresponding liquid cooling cabinet 10 to supply power to the liquid cooling cabinet 10. The network line 40 includes a horizontal network wire 401, at least one longitudinal network wire 402 connected to the horizontal network wire 401, and a network branch wire 403 connected to the at least one longitudinal network wire 402. The network branch wire 403 is adapted to be electrically connected to a corresponding liquid cooling cabinet 10 to provide a control signal to the liquid cooling cabinet 10 or receive a signal indicating the operation state thereof from the liquid cooling cabinet 10. The horizontal power supply wire 301 and the horizontal network line 401 are disposed on the top of the rack 20, such as in a horizontal cable tray 501 above a ceiling 52. The at least one longitudinal power supply wire 302 and at least one longitudinal network wire 402 are disposed in the vertical cable tray (502). In such an embodiment, since the waterline is disposed separately from the power supply and network lines, the safety of the system may be further improved.

In some embodiments, as shown in FIG. 3, the water supply horizontal pipe 1411 and the water return horizontal pipe 1421 are disposed below the suspended floor 51. In other embodiments, the water supply horizontal pipe 1411 and the water return horizontal pipe 1421 may be disposed on the ground, which is not limited in the embodiments of the present disclosure.

In some embodiments, the water supply horizontal pipe 1411, the water return horizontal pipe 1421, the horizontal power supply wire 301, and the horizontal network wire 401 may be all disposed below the floor 51. In some embodiments, the water supply horizontal pipe 1411, the water return horizontal pipe 1421, the horizontal power supply wire 301, and the horizontal network wire 401 may all be disposed above the ceiling 52. In some embodiments, the water supply horizontal pipe 1411, the water return horizontal pipe 1421, and the horizontal power supply wire 301 may be disposed below the floor 51, while the horizontal network wire 401 is disposed above the ceiling 52. In some embodiments, the water supply horizontal pipe 1411, the water return horizontal pipe 1421, and the horizontal power supply wire 301 may be disposed above the ceiling 52, while the horizontal network wire 401 is disposed below the floor 51. In some embodiments, the water supply horizontal pipe 1411, the water return horizontal pipe 1421, and the horizontal network wire 401 may be disposed below the floor 51, while the horizontal power supply wire 301 is disposed above the ceiling 52. In some embodiments, the water supply horizontal pipe 1411, the water return horizontal pipe 1421, and the horizontal network wire 401 may be disposed above the ceiling 52, while the horizontal power supply wire 301 is disposed below the floor 51.

In some embodiments, the liquid cooling cabinet bearing apparatus further includes a plurality of groups of blind mate interfaces, wherein each group of blind mate interfaces is adapted to be connected to a water supply connector, a water return connector, a power supply connector and a network connector of the corresponding liquid cooling cabinet 10. With such an arrangement, after the liquid cooling cabinet 10 is placed on the mounting base 202, the water supply connector, the water return connector, the power supply connector and the network connector of the liquid cooling cabinet 10 may be easily aligned with the cooling water supply pipe 141, the cooling water return pipe 142, the horizontal power supply wire 301 and the horizontal network wire 401. In other embodiments, instead of the blind mate interfaces, the liquid cooling cabinet bearing apparatus may also include a non-blind mate type interface adapted to be connected the water supply connector, the water return connector, the power supply connector and the network connector of the liquid cooling cabinet 10 to the cooling water supply pipe 141, the cooling water return pipe 142, the horizontal power supply wire 301 and the horizontal network wire 401, respectively.

In some embodiments, the bottom of the liquid cooling cabinet 10 is provided with rollers for assisting the corresponding liquid cooling cabinet 10 to move horizontally on the mounting base 202. When the liquid cooling cabinet 10 is placed on the corresponding mounting base 202 for being pushed, the rollers can assist the horizontal movement of the liquid cooling cabinet 10 on the mounting base 202, so that the liquid cooling cabinet 10 may be more easily pushed to the installation position. The mounting base 202 is provided with mounting holes. After the liquid cooling cabinet 10 is placed on the mounting base 202, the liquid cooling cabinet 10 may be fixed to the mounting holes by fasteners such as bolts or L-shaped angle steel.

In some embodiments, the rack 20 is provided with a stair and an operation and maintenance channel, so as to install the liquid cooling cabinet 10 and route the wire when installing the rack for the first time, and may perform simple maintenance operations in a later period, such as maintenance of electricity, waterline, power supply cable, and network cable.

In some embodiments, as shown in FIG. 3, the liquid cooling cabinet bearing apparatus further includes an operation and maintenance assembly 60, and the operation and maintenance assembly 60 is separated from the rack 20 and may horizontally move on the floor 51. The operation and maintenance assembly 60 includes a base 601, a roller 602, a vertical rod 603, and a supporting part 604. The roller 602 is disposed at the bottom of the base 601, so that the operation and maintenance assembly 60 may be horizontally moved on the floor 51. The vertical rod 603 is disposed at the top of the base 601. The supporting part 604 is configured to support the liquid cooling cabinet 10. The supporting part 604 may be provided with a fastener for fixing the liquid cooling cabinet 10. The supporting part 604 is disposed on the vertical rod 603 and may be moved up and down along the vertical rod 603, so that the supporting part 604 can be moved to the same height as each layer of the mounting bases 202, so as the liquid cooling cabinet 10 on the supporting part 604 may be moved to the corresponding mounting base 202 or the faulty liquid cooling cabinet 10 on the mounting base 202 may be moved to the supporting part 604.

In some embodiments, the operation and maintenance assembly 60 further includes a temporary cooling apparatus for temporarily providing a cold quantity to the liquid cooling cabinet 10 on the support part 604. In this way, the liquid cooling cabinet 10 may be temporarily cooled before the liquid cooling cabinet 10 on the supporting part 604 is moved to the corresponding mounting base 202.

The immersion liquid cooling scheme is different from the air cooling scheme, wherein there is no requirement of complex matching structures such as air supply under the floor and isolation of cold and hot channels, so that it is suitable for multi-layer stack placement. In addition, the power supply, the cold supply, the weak electricity monitoring, and the like of the liquid cooling cabinet 10 are similar to those of the air cooling server, and are already very mature in the air cooling machine room, wherein they are generally connected by a vertical cable tray under the floor or above the ceiling, thus the structure of the multi-layer stereoscopic data center may be well adapted.

According to the embodiment of the present disclosure, the liquid cooling cabinet of the immersion liquid cooling system is stacked and installed, thereby the height space of the machine room can be utilized to the maximum extent, and the immersion liquid cooling data center is constructed on three-dimension, so that the power density per the unit area of the machine room can be further improved, and the occupied area is saved.

In addition, the intensive design of the stereoscopic immersion liquid cooling machine room may reduce the cost of matching design and investment, and may realize the compatible civil engineering design with the air cooling machine room.

In addition, the water supply and return, power supply and network cables can be standardized in design and routing through the cable tray, so that replication and large-scale popularization are facilitated, and the number of cable trays can be saved in the stereoscopic scheme.

In addition, a staircase and a maintenance channel are reserved in the stereoscopic data center for the initial installation and subsequent maintenance, maintenance without opening the cover may be carried out in a reserved operation and maintenance channel, and maintenance requiring opening the cover may be carried out after the liquid cooling cabinet lands on the first floor by the operation and maintenance assembly.

Various embodiments of the present disclosure have been described above, which are exemplary, not exhaustive, and are not limited to the embodiments disclosed. Many modifications and variations will be apparent to those of ordinary skill in the art without departing from the scope and spirit of the illustrated embodiments. The selection of the terms used herein is intended to best explain the principles, practical applications, or technical improvements in the marketplace of the embodiments, or to enable others of ordinary skill in the art to understand the embodiments disclosed herein.

1. A liquid cooling cabinet bearing apparatus comprising:
a rack comprising a plurality of vertical support structures and at least one layer of mounting bases supported by the plurality of vertical support structures, wherein each layer of the mounting bases comprises a plurality of mounting bases for bearing a corresponding liquid cooling cabinet respectively, and at least a part of the plurality of vertical support structures is provided with a pipeline arrangement channel extending along a length direction thereof;
a cooling water supply pipe comprising a water supply horizontal pipe at least one water supply longitudinal pipe in communication with the water supply horizontal pipe, and a water supply branch pipe in communication with the at least one water supply longitudinal pipe and configured to provide cooling water to a corresponding liquid cooling cabinet, wherein the water supply horizontal pipe is disposed outside the pipeline arrangement channel, and the at least one water supply longitudinal pipe and a corresponding water supply branch pipe are disposed in a corresponding pipeline arrangement channel;
a cooling water return pipe comprising a water return horizontal pipe at least one water return longitudinal pipe in communication with the water return horizontal pipe, and a water return branch pipe in communication with the at least one water return longitudinal pipe and configured to receive heated cooling water from a corresponding liquid cooling cabinet, wherein the water return horizontal pipe is disposed outside the pipeline arrangement channel, and the at least one water return longitudinal pipe and a corresponding water return branch pipe are disposed in a corresponding pipeline arrangement channel; and
an electrical line disposed outside the pipeline arrangement channel and adapted to be electrically connected to a corresponding liquid cooling cabinet.

2. The liquid cooling cabinet bearing apparatus of claim 1, wherein the water supply horizontal pipe and the water return horizontal pipe are disposed below the rack, and the electrical line is connected to a corresponding liquid cooling cabinet from a top of the rack.

3. The liquid cooling cabinet bearing apparatus of claim 2, wherein the water supply horizontal pipe and the water return horizontal pipe are disposed below a floor or on the ground.

4. The liquid cooling cabinet bearing apparatus of claim 2, wherein the electrical line comprises a power supply line and a network line;
the power supply line comprises a horizontal power supply wire, at least one longitudinal power supply wire connected to the horizontal power supply wire, and a power supply branch wire connected to the at least one longitudinal power supply wire wherein the power supply branch wire is adapted to be electrically connected to a corresponding liquid cooling cabinet;
the network line comprises a horizontal network wire, at least one longitudinal network wire connected to the horizontal network wire, and a network branch wire connected to the at least one longitudinal network wire, wherein the network branch wire is adapted to be electrically connected to a corresponding liquid cooling cabinet; and
the horizontal power supply wire and the horizontal network wire are disposed in a horizontal cable tray above a ceiling and the at least one longitudinal power supply wire and the at least one longitudinal network wire are disposed in a vertical cable tray.

5. The liquid cooling cabinet bearing apparatus of claim 1, wherein the electrical line comprises a power supply line and a network line; the power supply line comprises a horizontal power supply wire, at least one longitudinal power supply wire connected to the horizontal power supply wire, and a power supply branch wire connected to the at least one longitudinal power supply wire, wherein the power supply branch wire is adapted to be electrically connected to a corresponding liquid cooling cabinet; the network line comprises a horizontal network wire, at least one longitudinal network wire connected to the horizontal network wire, and a network branch wire connected to the at least one longitudinal network wire, wherein the network branch wire is adapted to be electrically connected to a corresponding liquid cooling cabinet; and
wherein the water supply horizontal pipe, the water return horizontal pipe, the horizontal power supply wire and the horizontal network wire are arranged in any one of the following ways:
the water supply horizontal pipe, the water return horizontal pipe, the horizontal power supply wire and the horizontal network wire are all disposed below a floor;
the water supply horizontal pipe, the water return horizontal pipe the horizontal power supply wire and the horizontal network wire are all disposed above a ceiling;
the water supply horizontal pipe, the water return horizontal pipe and the horizontal power supply wire are disposed below the floor, and the horizontal network wire is disposed above the ceiling;
the water supply horizontal pipe, the water return horizontal pipe and the horizontal power supply wire are disposed above the ceiling, and the horizontal network wire is disposed below the floor;
the water supply horizontal pipe, the water return horizontal pipe and the horizontal network wire are disposed below the floor, and the horizontal power supply wire is disposed above the ceiling; or
the water supply horizontal pipe, the water return horizontal pipe and the horizontal network wire are disposed above the ceiling, and the horizontal power supply wire is disposed below the floor.

6. The liquid cooling cabinet bearing apparatus of claim 1, wherein the rack comprises two layers of the mounting bases.

7. The liquid cooling cabinet bearing apparatus of claim 1, further comprising a plurality of groups of blind mate interfaces, wherein each group of blind mate interfaces is adapted to be connected to a water supply connector, a water return connector, a power supply connector and a network connector of a corresponding liquid cooling cabinet.

8. The liquid cooling cabinet bearing apparatus of claim 1, wherein the at least one layer of mounting bases is provided with a mounting hole for fixing a corresponding liquid cooling cabinet through a fastener.

9. The liquid cooling cabinet bearing apparatus of claim 1, wherein the rack is made of steel structure, and is provided with stairs and operation and maintenance channels.

10. The liquid cooling cabinet bearing apparatus of claim 1, further comprising an operation and maintenance assembly separated from the rack and comprising:
a base;
a roller disposed at a bottom of the base;
a vertical rod disposed at a top of the base; and
a supporting part for supporting the liquid cooling cabinet, the supporting part being disposed on the vertical rod and able to move along the vertical rod to a same height as each layer of the mounting bases.

11. The liquid cooling cabinet bearing apparatus of claim 10, wherein the operation and maintenance assembly further comprises a temporary cooling apparatus for temporarily providing a cold quantity to the liquid cooling cabinet on the supporting part.
